(19) United States
(12) Patent Application Publication
(10) Pub. No.: US 2025/0391488 A1
(43) Pub. Date: Dec. 25, 2025

(54) STORAGE DEVICE INCLUDING NONVOLATILE MEMORY AND MEMORY CONTROLLER AND OPERATING METHOD OF STORAGE DEVICE

(71) Applicant: Samsung Electronics Co., Ltd., Suwon-si (KR)

(72) Inventor: Sang-In Park, Suwon-si (KR)

(21) Appl. No.: 19/226,833

(22) Filed: Jun. 3, 2025

(30) Foreign Application Priority Data
Jun. 19, 2024 (KR) 10-2024-0079773

(51) Int. Cl. G11C 29/40; G11C 16/34; G11C 29/12

(52) U.S. Cl. CPC G11C 29/40; G11C 16/349; G11C 29/1201; G11C 2029/1202; G11C 2029/4002

(57) ABSTRACT

A storage device includes a first nonvolatile memory that includes a plurality of memory blocks including a first memory block and a second memory block, generates a reference counting value by counting the number of stuck bits associated with the first and second memory blocks at a first power-on, and generates one or more comparison counting values by repeatedly counting the number of the stuck bits at one or more time points after the first power-on, and a memory controller that receives the reference counting value and the one or more comparison counting values from the first nonvolatile memory, generates one or more comparison result data by comparing the reference counting value with each of the one or more comparison counting values, and repeatedly performs a chip verification operation on the first nonvolatile memory based on each of the one or more comparison result data.

### CROSS-REFERENCE TO RELATED APPLICATIONS

This application claims priority under 35 U.S.C. § 119 to Korean Patent Application No. 10-2024-0079773 filed on Jun. 19, 2024, in the Korean Intellectual Property Office, the entirety of which is incorporated by reference herein.

### BACKGROUND

A semiconductor memory is classified as a volatile memory, which loses data stored therein when a power is turned off, such as a static random access memory (SRAM) or a dynamic random access memory (DRAM), or a nonvolatile memory, which retains data stored therein even when a power is turned off, such as a flash memory, a phase-change RAM (PRAM), a magnetic RAM (MRAM), a resistive RAM (RRAM), or a ferroelectric RAM (FRAM).

A micro crack may occur in the process of manufacturing the nonvolatile memory. The micro crack may mean a crack which is not detected in a test process performed after the nonvolatile memory is manufactured. The range of the micro crack may be expanded to various use environments, thereby causing the reduction of reliability of the nonvolatile memory. Accordingly, there is required a method of periodically monitoring the micro crack to improve the reliability of the nonvolatile memory or the storage device.

### SUMMARY

Some aspects of the present disclosure provide storage devices including a nonvolatile memory and a memory controller for periodically monitoring a micro crack, and operating methods of the storage devices.

According to some implementations, a storage device includes a first nonvolatile memory that includes a plurality of memory blocks including a first memory block and a second memory block, generates a reference counting value by counting the number of stuck bits associated with the first and second memory blocks at a first power-on, and generates one or more comparison counting values by repeatedly counting the number of the stuck bits at one or more time points after the first power-on, and a memory controller that receives the reference counting value and the one or more comparison counting values from the first nonvolatile memory, generates one or more comparison result data by comparing the reference counting value with each of the one or more comparison counting values, and repeatedly performs a chip verification operation on the first nonvolatile memory based on each of the one or more comparison result data.

According to some implementations, a storage device includes a first nonvolatile memory that includes a plurality of memory blocks including a first memory block and a second memory block, generates a reference counting value by counting the number of stuck bits associated with the first and second memory blocks at a first power-on, generates one or more comparison counting values by repeatedly counting the number of the stuck bits at one or more time points after the first power-on, and generates one or more comparison result data by comparing the reference counting value with each of the one or more comparison counting values, and a memory controller that receives the one or more comparison result data from the first nonvolatile memory and repeatedly performs a chip verification operation on the first nonvolatile memory based on each of the one or more comparison result data.

According to some implementations, an operating method of a storage device which includes a nonvolatile memory including a first memory block and a second memory block and a memory controller controlling the nonvolatile memory includes generating, at the nonvolatile memory, a reference counting value by counting the number of stuck bits associated with the first and second memory blocks at a first power-on, generating, at the nonvolatile memory, a first comparison counting value by counting the number of the stuck bits associated with the first and second memory blocks at a first time point after the first power-on, transmitting, at the nonvolatile memory, the reference counting value and the first comparison counting value to the memory controller, generating, at the memory controller, first comparison result data by comparing the reference counting value and the first comparison counting value received from the nonvolatile memory, and performing, at the memory controller, a chip verification operation on the nonvolatile memory based on the first comparison result data.

### BRIEF DESCRIPTION OF THE DRAWINGS

The above and other objects and features of the present disclosure will become apparent by describing in detail examples thereof with reference to the accompanying drawings.

FIG. 1 illustrates an example of a storage device.

FIG. 2 illustrates an example of a memory controller of FIG. 1.

FIG. 3 illustrates an example of a nonvolatile memory of FIG. 1.

FIG. 4 illustrates an example of one memory block BLK of a plurality of memory blocks included in a memory cell array of FIG. 3.

FIG. 5 illustrates an example of a threshold voltage distribution of memory cells included in a memory block of FIG. 4.

FIG. 6 illustrates an example of an operating method of a storage device.

FIG. 7 illustrates an example of a chip verification operating method of a storage device.

FIG. 8 illustrates an example of an operating method of a nonvolatile memory generating a counting value.

FIG. 9 illustrates an example of an operating method of a nonvolatile memory generating a comparison counting value.

FIG. 10 illustrates an example of a nonvolatile memory.

FIG. 11 illustrates a micro crack occurring in a nonvolatile memory.

FIG. 12 illustrates an example of an operating method of a memory controller.

FIG. 13 illustrates an example of a storage device.

FIGS. 14A and 14B illustrate an example of a BIST circuit of FIG. 13.

FIG. 15 illustrates an example of an operating method of a comparison logic circuit.

FIG. 16 illustrates an example of an SSD system to which a nonvolatile memory is applied.

FIG. 17 illustrates an example of a storage system.

FIG. 18 illustrates an example of a test system.

### DETAILED DESCRIPTION

In the detailed description, components which are described with reference to the terms “unit”, “module”, “block”, “˜er or ˜or”, etc. and function blocks which are illustrated in drawings will be implemented in the form of software or hardware or a combination thereof. For example, the software may include a machine code, firmware, an embedded code, and application software. For example, the hardware may include an electrical circuit, an electronic circuit, a processor, a computer, an integrated circuit, integrated circuit cores, a pressure sensor, an inertial sensor, a microelectromechanical system (MEMS), a passive element, or a combination thereof.

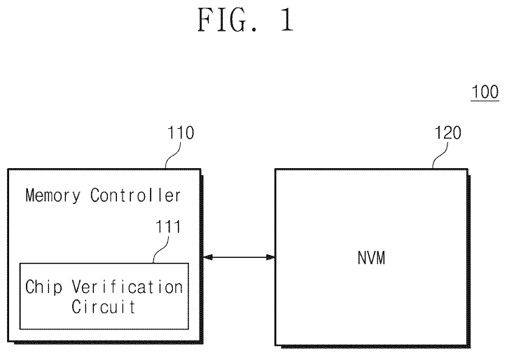

FIG. 1 is a diagram illustrating a storage device according to some implementations of the present disclosure. Referring to FIG. 1, a storage device 100 may include a memory controller 110 and a nonvolatile memory chip (hereinafter referred to as a “nonvolatile memory”) 120. Under control of an external device (e.g., an external device host, a central processing unit (CPU), or an application processor (AP)), the memory controller 110 may store data in the nonvolatile memory 120 or may read data stored in the nonvolatile memory 120.

The nonvolatile memory 120 may include a plurality of memory blocks. Under control of the memory controller 110, the nonvolatile memory 120 may store data in the plurality of memory blocks or may provide data stored in the plurality of memory blocks to the memory controller 110. As an example, the nonvolatile memory 120 may be a NAND flash memory device, but the present disclosure is not limited thereto.

The memory controller 110 accord may include a chip verification circuit 111. The chip verification circuit 111 may determine whether the nonvolatile memory 120 is an unusable chip, or otherwise defective, by repeatedly performing a chip verification operation on the nonvolatile memory 120. When the chip verification circuit 111 determines that the nonvolatile memory 120 is an unusable chip, the memory controller 110 may manage the nonvolatile memory 120 as an unusable chip. For example, when the chip verification circuit 111 determines that the nonvolatile memory 120 is an unusable chip, the memory controller 110 may control the nonvolatile memory 120 such that the use of the nonvolatile memory 120 is stopped.

In some implementations, the chip verification operation refers to an operation of determining whether the nonvolatile memory 120 is an unusable chip, by comparing a difference of the numbers of stuck bits associated with memory blocks selected at different time points. The chip verification operation will be described in additional detail below.

As described above, the storage device 100 may repeatedly perform the chip verification operation on the nonvolatile memory 120. When the numbers of stuck bits associated with selected memory blocks increases, the storage device 100 may determine that a range (e.g., extent, length, width, or other dimension) of a micro crack present in the nonvolatile memory 120 increases and may manage the nonvolatile memory 120 as an unusable chip. Alternatively, or in addition, when the number of stuck bits associated with selected memory blocks increases, the storage device 100 may determine that a micro crack occurs in the nonvolatile memory 120 and may manage the nonvolatile memory 120 as an unusable chip. Accordingly, because the micro crack present in the nonvolatile memory 120 is capable of being monitored, the reliability of the nonvolatile memory 120 or the storage device 100 may be improved.

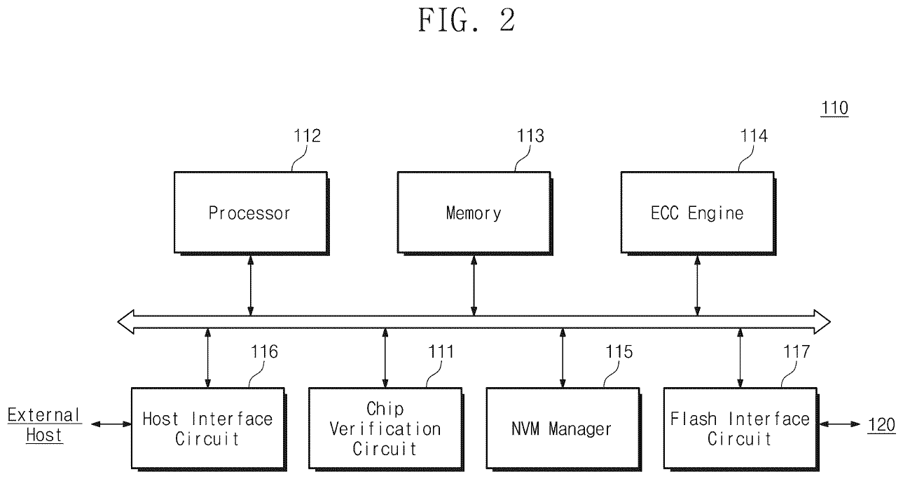

FIG. 2 illustrates a memory controller of FIG. 1. Referring to FIGS. 1 and 2, the memory controller 110 may include the chip verification circuit 111, a processor 112, a memory 113, an error correction code (ECC) engine 114, a nonvolatile memory manager 115, a host interface circuit 116, and a flash interface circuit 117.

The chip verification circuit 111 may be configured to perform the chip verification operation on a selected memory block to detect the increase in a range of a micro crack. The chip verification operation of the chip verification circuit 111 will be described in detail with reference to the following drawings.

The processor 112 may control all the operations of the memory controller 110. The memory 113 may be used as a working memory, a buffer memory, or a system memory of the memory controller 110. In some implementations, the memory 113 includes a volatile memory such as an SRAM or a DRAM. The processor 112 may process information stored in the memory 113 or may execute various firmware or program codes stored in the memory 113.

The ECC engine 114 may be configured to detect and correct an error of data read from the nonvolatile memory 120. For example, the ECC engine 114 may generate an error correction code for data to be stored in the nonvolatile memory 120. The generated error correction code may be stored in the nonvolatile memory 120 together with the corresponding data. Afterwards, the error correction code and the corresponding data may be read from the nonvolatile memory 120, and the ECC engine 114 may be configured to correct an error of data read from the nonvolatile memory 120 by using the error correction code. In some implementations, the ECC engine 114 has an error correction capability of a given level.

The nonvolatile memory manager 115 may perform various management operations on the nonvolatile memory 120. For example, the nonvolatile memory manager 115 may perform various maintenance operations such as a mapping table managing operation of managing mapping information between a physical address of the nonvolatile memory 120 and a logical address of the stored data, a lifetime managing operation of managing the lifetime of the nonvolatile memory 120 (e.g., a plurality of memory blocks of the nonvolatile memory 120), a bad block managing operation of managing a bad block of the nonvolatile memory 120, a wear leveling operation of managing the wear-leveling of the nonvolatile memory 120, and a garbage collection operation for securing free memory blocks of the nonvolatile memory 120. In some implementations, the nonvolatile memory manager 115 is implemented with a flash translation layer (FTL) configured to perform the management operation on the nonvolatile memory 120.

The nonvolatile memory manager 115 may manage the nonvolatile memory 120 as an unusable chip, based on a result of the chip verification operation by the chip verification circuit 111.

The chip verification circuit 111 and the nonvolatile memory manager 115 may be implemented in the form of software, firmware, hardware, or a combination thereof. The chip verification circuit 111 and the nonvolatile memory manager 115 which are implemented in the form of software or firmware may be stored in the memory 113, and the chip verification circuit 111 and the nonvolatile memory manager 115 stored in the memory 113 may be executed by the processor 112.

The memory controller 110 may communicate with an external host through the host interface circuit 116. The host interface circuit 116 may be implemented based on the given interface protocol. In some implementations, the given interface protocol may include at least one of protocols for various interfaces such as a peripheral component interconnect express (PCI-express) interface, a non-volatile memory express (NVMe) interface, a serial ATA (SATA) interface, a serial attached SCSI (SAS) interface, and a universal flash storage (UFS) interface, but the interfaces are not limited thereto.

The memory controller 110 may communicate with the nonvolatile memory 120 through the flash interface circuit 117. For example, the flash interface circuit 117 may be implemented based on a NAND interface, a toggle interface, or an ONFI interface. In some implementations, the flash interface circuit 117 includes a flash memory controller (FMC) configured to control a plurality of nonvolatile memories independently.

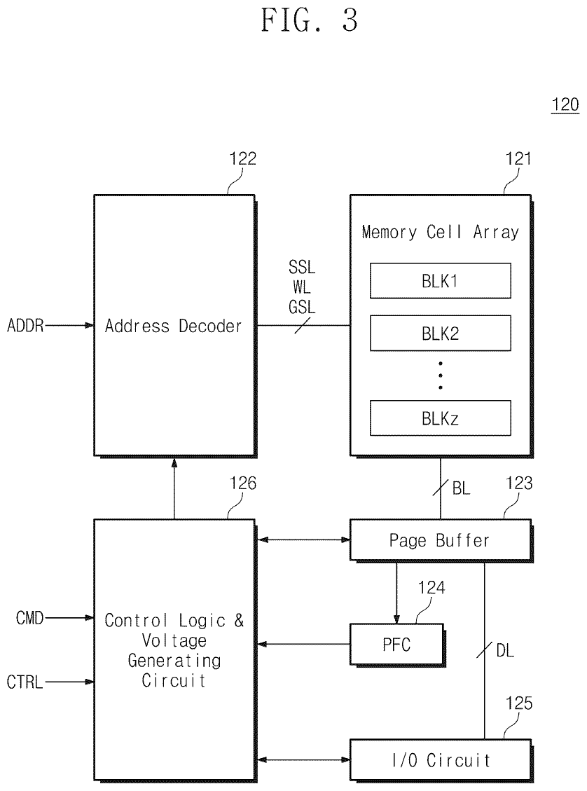

FIG. 3 illustrates a nonvolatile memory of FIG. 1. Referring to FIGS. 1 and 3, the nonvolatile memory 120 may include a memory cell array 121, an address decoder 122, a page buffer 123, a pass/fail check circuit 124, an input/output circuit 125, a control logic and voltage generating circuit 126.

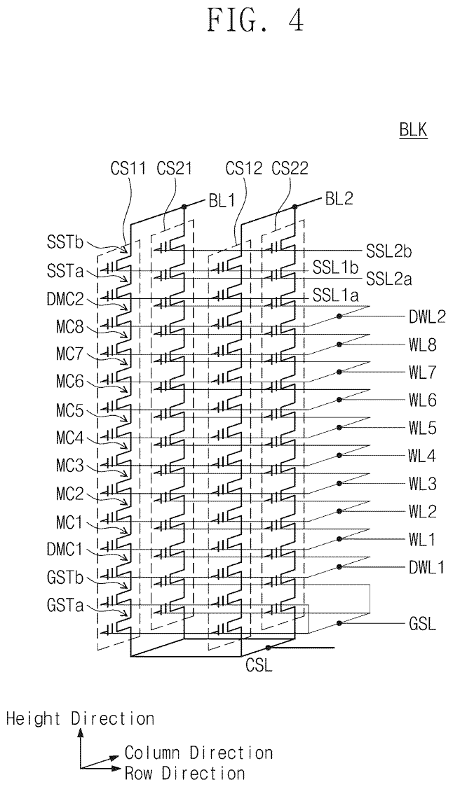

The memory cell array 121 includes a plurality of memory blocks BLK1 to BLKz. Each of the plurality of memory blocks BLK1 to BLKz may include a plurality of memory cells. A structure of a memory block will be described in detail with reference to FIG. 4.

In some implementations, the plurality of memory blocks BLK1 to BLKz are stacked to be perpendicular to a substrate. For example, the plurality of memory blocks BLK1 to BLKz may be connected to a plurality of bit lines extending in a first direction. The plurality of memory blocks BLK1 to BLKz may be vertically stacked along the first direction. The first memory block BLK1 may be located at the uppermost of the plurality of memory blocks BLK1 to BLKz, and the second memory block BLK2 may be located adjacent to the first memory block BLK1.

The address decoder 122 may be connected to the memory cell array 121 through string selection lines SSL, word lines WL, and ground selection lines GSL. The address decoder 122 may decode an address ADDR received from the memory controller 110 and may control the string selection lines SSL, the word lines WL, and the ground selection lines GSL based on a decoding result.

The page buffer 123 may be connected to the memory cell array 121 through bit lines BL. The page buffer 123 may temporarily store data stored in memory cells of the memory cell array 121 through the bit lines BL. The page buffer 123 may control levels of the bit lines BL based on data received from the input/output circuit 125 through data lines DL.

In some implementations, the page buffer 123 stores data to be written in memory cells of the memory cell array 121. The page buffer 123 may apply voltages to the bit lines BL based on the stored data. In the read operation or in the verify read operation which is performed in the program operation or the erase operation, the page buffer 123 may sense voltages of the bit lines BL and may store a sensing result.

In the verify read operation associated with the program operation or the erase operation, the pass/fail check circuit 124 may verify the sensing result of the page buffer 123. For example, in the verify read operation which is performed in the program operation, the pass/fail check circuit 124 may count a number of values corresponding to a memory cell (i.e., an on-cell) which is not programmed to a target threshold voltage or higher, e.g., a number of such memory cells.

In the verify read operation which is performed in the erase operation, the pass/fail check circuit 124 may count a number of values corresponding to a memory cell (e.g., an off-cell) which is not erased to a target threshold voltage or lower, e.g., a number of such memory cells.

When the counted value is greater than or equal to a threshold value, the pass/fail check circuit 124 may output a fail signal to the control logic and voltage generating circuit 126 (hereinafter referred to as a “control logic circuit”). When the counting result is smaller than the threshold value, the pass/fail check circuit 124 may output a pass signal to the control logic circuit 126. Depending on the verification result of the pass/fail check circuit 124, a program loop of the program operation may be further performed, or an erase loop of the erase operation may be further performed.

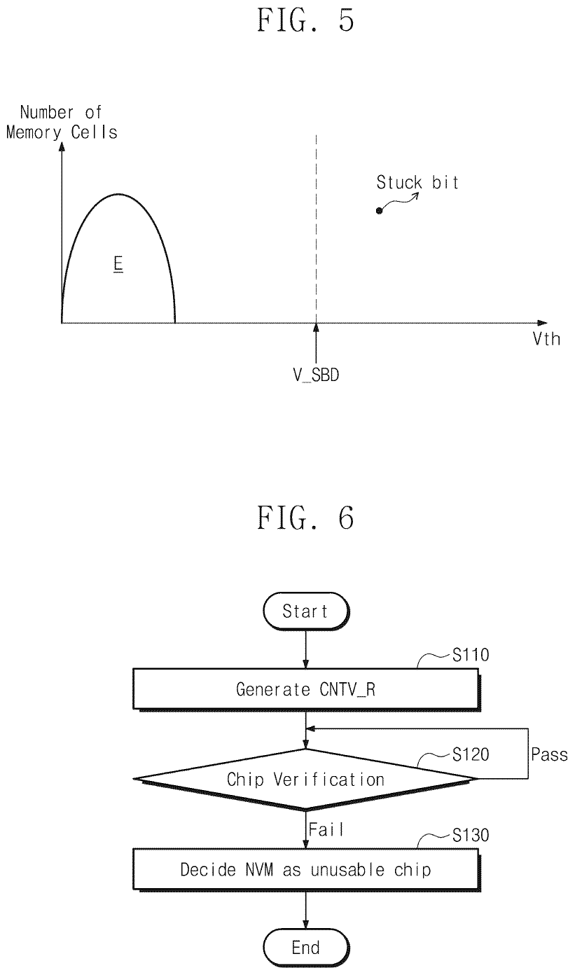

In some implementations, after the erase operation or the verify read operation of the erase operation, the pass/fail check circuit 124 counts the number of stuck bits in association with at least some of the plurality of memory blocks BLK1 to BLKz. The operation of counting the number of stuck bits will be described in detail with reference to FIGS. 5 to 10.

The input/output circuit 125 may receive data from the page buffer 123 through the data lines DL and may transfer the received data to the memory controller 110. The input/output circuit 125 may transfer data received from the memory controller 110 to the page buffer 123 through the data lines DL.

The control logic circuit 126 may control components of the nonvolatile memory 120 in response to a command CMD and a control signal CTRL from the memory controller 110. The control logic circuit 126 may generate various voltages used for the nonvolatile memory 120 to operate. For example, the control logic circuit 126 may generate various voltages such as a plurality of program voltages, a plurality of program verify voltages, a plurality of read voltages, a plurality of erase voltages, and a plurality of erase verify voltages. Various voltages (e.g., an erase voltage or an erase verify voltage) to be described below may be generated by the control logic circuit 126 and may be provided to a corresponding word line through the address decoder 122 or may be provided to the substrate where the nonvolatile memory 120 is formed.

In some implementations, the nonvolatile memory 120 is manufactured in a bonding method. The memory cell array 121 may be manufactured by using a first wafer, and the address decoder 122, the page buffer 123, the pass/fail check circuit 124, the input/output circuit 125, and the control logic circuit 126 may be manufactured by using a second wafer. The nonvolatile memory 120 may be implemented by coupling the first wafer and the second wafer such that an upper surface of the first wafer and an upper surface of the second wafer face each other.

In some implementations, the nonvolatile memory 120 is manufactured in a cell over peri (COP) method. A peripheral circuit including the address decoder 122, the page buffer 123, the pass/fail check circuit 124, the input/output circuit 125, and control logic circuit 126 may be implemented on a substrate. The memory cell array 121 may be implemented over the peripheral circuit. The peripheral circuit and the memory cell array 121 may be connected by using the through vias.

FIG. 4 illustrates one memory block BLK of a plurality of memory blocks included in a memory cell array of FIG. 3. One memory block BLK will be described with reference to FIG. 4, but the present disclosure is not limited thereto. The plurality of memory blocks BLK1 to BLKz included in the memory cell array 121 may be similar to or the same as the memory block BLK of FIG. 4 in structure. Referring to FIGS. 3 and 4, the memory block BLK may include a plurality of cell strings CS11, CS12, CS21, and CS22. The plurality of cell strings CS11, CS12, CS21, and CS22 may be arranged in a row direction and a column direction.

Cell strings located at the same column from among the plurality of cell strings CS11, CS12, CS21, and CS22 may be connected to the same bit line. For example, the cell strings CS11 and CS21 may be connected to a first bit line BL1, and the cell strings CS12 and CS22 may be connected to a second bit line BL2. Each of the plurality of cell strings CS11, CS12, CS21, and CS22 includes a plurality of cell transistors. Each of the plurality of cell transistors may include a charge trap flash (CTF) memory cell, but the present disclosure is not limited thereto. The plurality of cell transistors may be stacked in a height direction being a direction perpendicular to a plane (e.g., a semiconductor substrate) which is perpendicular to a plane defined by the row direction and the column direction.

The plurality of cell transistors may be connected in series between the corresponding bit line (e.g., BL1 or BL2) and a common source line CSL. For example, the plurality of cell transistors may include string selection transistors SSTa and SSTb, dummy memory cells DMC1 and DMC2, memory cells MC1 to MC8, and ground selection transistors GSTa and GSTb. The serially-connected string selection transistors SSTa and SSTb may be provided or connected between the serially-connected memory cells MC1 to MC8 and the corresponding bit line (e.g., BL1 and BL2). The serially-connected ground selection transistors GSTa and GSTb may be provided or connected between the serially-connected memory cells MC1 to MC8 and the common source line CSL. In some implementations, the second dummy memory cell DMC2 is provided between the serially-connected string selection transistors SSTa and SSTB and the serially-connected memory cells MC1 to MC8, and the first dummy memory cell DMC1 may be provided between the serially-connected memory cells MC1 to MC8 and the serially-connected ground selection transistors GSTa and GSTb.

In each of the plurality of cell strings CS11, CS12, CS21, and CS22, memory cells located at the same height from among the memory cells MC1 to MC8 may share the same word line. For example, the first memory cells MC1 of the plurality of cell strings CS11, CS12, CS21, and CS22 may be located at the same height from the substrate and may share a first word line WL1. The second memory cells MC2 of the plurality of cell strings CS11, CS12, CS21, and CS22 may be located at the same height from the substrate and may share a second word line WL2. Likewise, the third to eighth memory cells MC3 to MC8 of the plurality of cell strings CS11, CS12, CS21, and CS22 may be placed at the same heights from the semiconductor substrate and may share the third to eighth word lines WL3 to WL8.

Dummy memory cells located at the same height from among the dummy memory cells DMC1 and DMC2 of the plurality of cell strings CS11, CS12, CS21, and CS22 may share the same dummy word line. For example, the first dummy memory cells DMC1 of the plurality of cell strings CS11, CS12, CS21, and CS22 may share a first dummy word line DWL1, and the second dummy memory cells DMC2 of the plurality of cell strings CS11, CS12, CS21, and CS22 may share a second dummy word line DWL2.

String selection transistors located at the same height and the same row from among the string selection transistors SSTa and SSTb of the plurality of cell strings CS11, CS12, CS21, and CS22 may share the same string selection line. For example, the string selection transistors SSTb of the cell strings CS11 and CS12 may be connected to a string selection line SSL1b, and the string selection transistors SSTa of the cell strings CS11 and CS12 may be connected to a string selection line SSL1a. The string selection transistors SSTb of the cell strings CS21 and CS22 may be connected to a string selection line SSL2b, and the string selection transistors SSTa of the cell strings CS21 and CS22 may be connected to a string selection line SSL2a.

Although not illustrated, string selection transistors located at the same row from among the string selection transistors SSTa and SSTb of the plurality of cell strings CS11, CS12, CS21, and CS22 may share the same string selection line. For example, the string selection transistors SSTa and SSTb of the cell strings CS11 and CS12 may share a first string selection line, and the string selection transistors SSTa and SSTb of the cell strings CS21 and CS22 may share a second string selection line different from the first string selection line.

Ground selection transistors located at the same height and the same row from among the ground selection transistors GSTa and GSTb of the plurality of cell strings CS11, CS12, CS21, and CS22 may be connected to the same ground selection line. Although not illustrated, the ground selection transistors GSTb of the cell strings CS11 and CS12 may be connected to a first ground selection line, and the ground selection transistors GSTa of the cell strings CS11 and CS12 may be connected to a second ground selection line. The ground selection transistors GSTb of the cell strings CS21 and CS22 may be connected to a third ground selection line, and the ground selection transistors GSTa of the cell strings CS21 and CS22 may be connected to a fourth ground selection line.

Although not illustrated, the ground selection transistors GSTa and GSTb of the plurality of cell strings CS11, CS12, CS21, and CS22 may share the same ground selection line. Alternatively, ground selection transistors located at the same height from among the ground selection transistors GSTa and GSTb of the plurality of cell strings CS11, CS12, CS21, and CS22 may share the same ground selection line. Alternatively, ground selection transistors located at the same row from among the ground selection transistors GSTa and GSTb of the plurality of cell strings CS11, CS12, CS21, and CS22 may share the same ground selection line.

In some implementations, each of the plurality of cell strings CS11, CS12, CS21, and CS22 of the memory block BLK further includes an erase control transistor (ECT). The erase control transistors ECT of the plurality of cell strings CS11, CS12, CS21, and CS22 may be located at the same height from the substrate and may be connected to the same erase control line (ECL). For example, in each of the plurality of cell strings CS11, CS12, CS21, and CS22, the erase control transistor ECT may be located between the common source line CSL and the ground selection transistor GSTa. Alternatively, the erase control transistor ECT may be located between the bit lines BL1 and BL2 and the string selection transistors SSTb. However, the present disclosure is not limited to those arrangements of the erase control transistor ECT.

The memory block BLK illustrated in FIG. 4 is provided as an example, and modifications thereof are also within the scope of this disclosure. For example, the number of cell strings may increase or decrease, and the number of rows of cell strings and the number of columns of cell strings may increase or decrease depending on the change in the number of cell strings. Also, the number of cell transistors (e.g., GST, GST, MC, and SST) of the memory block BLK may increase or decrease, and the height of the memory block BLK may increase or decrease depending of the number of cell transistors. In addition, the number of lines GSL, WL, DWL, and SSL connected to the cell transistors may increase or decrease depending on the number of cell transistors.

FIG. 5 illustrates a threshold voltage distribution of memory cells included in a memory block of FIG. 4. In FIG. 5, the horizontal axis represents a threshold voltage of a memory cell, and the vertical axis represents the number of memory cells.

Referring to FIGS. 1, 4, and 5, the nonvolatile memory 120 may perform the erase operation on the memory block BLK under control of the memory controller 110 or without control of the memory controller 110. In the erase operation on the memory block BLK, memory cells of the memory block BLK may be erased to form a threshold voltage distribution of an erase state “E”. For example, the nonvolatile memory 120 may perform the erase operation on the memory block BLK by applying the erase voltage to the substrate where the memory block BLK is located and applying the word line erase voltage (e.g., 0 V) to the word lines connected to the memory block BLK. However, the scope of the present disclosure is not limited thereto. For example, the erase operation may be performed through various methods.

In some implementations, the erase operation is performed based on an incremental step pulse erase (ISPE) method. For example, the erase operation may include a plurality of erase loops. Each of the plurality of erase loops may include an erase step of lowering a threshold voltage distribution of memory cells of a selected memory block and a verify step of verifying an erase state of the memory cells of the selected memory block. After all the erase loops are executed, when it is determined in the verify step that the erase operation on the selected memory block is passed, the memory block BLK may be determined as being erased normally by the erase operation. Below, for convenience the description, it is assumed that the memory block BLK is determined as being normally erased after the erase operation.

After the erase operation, the nonvolatile memory 120 may apply a stuck bit detection voltage V_SBD (e.g., 5 V) for detecting a stuck bit of the memory block BLK. When a micro crack is present in the memory cell array 121, threshold voltages of specific memory cells of the memory block BLK may be determined as being higher than the stuck bit detection voltage V_SBD. In this case, memory cells determined as having a threshold voltage higher than the stuck bit detection voltage V_SBD may not be turned on by the stuck bit detection voltage V_SBD.

In some implementations, the nonvolatile memory 120 detects a stuck bit, based on the number of bit lines corresponding to the turned-off memory cells (or the number of memory cells not turned on). For example, when the stuck bit detection voltage V_SBD is applied to the memory block BLK, the number of bit lines connected to memory cells whose threshold voltages are higher than the stuck bit detection voltage V_SBD (e.g., the number of bit lines being influenced or affected by a micro crack or the number of bit lines broken by the micro crack) may be detected as the number of stuck bits.

In some implementations, the nonvolatile memory 120 detects a stuck bit, based on the number of bit lines corresponding to turned-off memory cells and the number of memory blocks. For example, when the stuck bit detection voltage V_SBD is applied to each of two or more memory blocks BLKs, a sum of the first number of bit lines connected to memory cells which are included in one memory block and have threshold voltages higher than the stuck bit detection voltage V_SBD (e.g., the first number of bit lines influenced or broken by the micro crack) and the second number of bit lines connected to memory cells which are included in the other memory block and have threshold voltages higher than the stuck bit detection voltage V_SBD (e.g., the second number of bit lines influenced or broken by the micro crack) may be detected as the number of stuck bits.

In some implementations, the nonvolatile memory 120 counts the number of stuck bits of the memory block BLK at each time point by using the stuck bit detection voltage V_SBD, and generates a counting value of stuck bits.

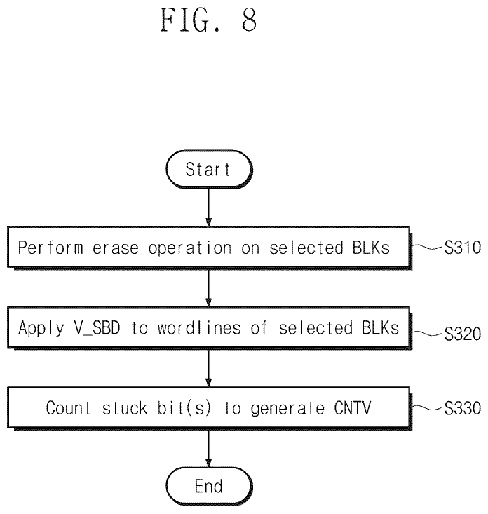

FIG. 6 illustrates an operating method of a storage device according to some implementations of the present disclosure. Referring to FIGS. 1 and 6, in operation S110, the storage device 100 generates a counting value (hereinafter referred to a “reference counting value CNTV_R”) by counting the number of stuck bits associated with memory blocks selected at a first power-on time point. The operation of generating the reference counting value CNTV_R will be described in detail with reference to FIG. 8.

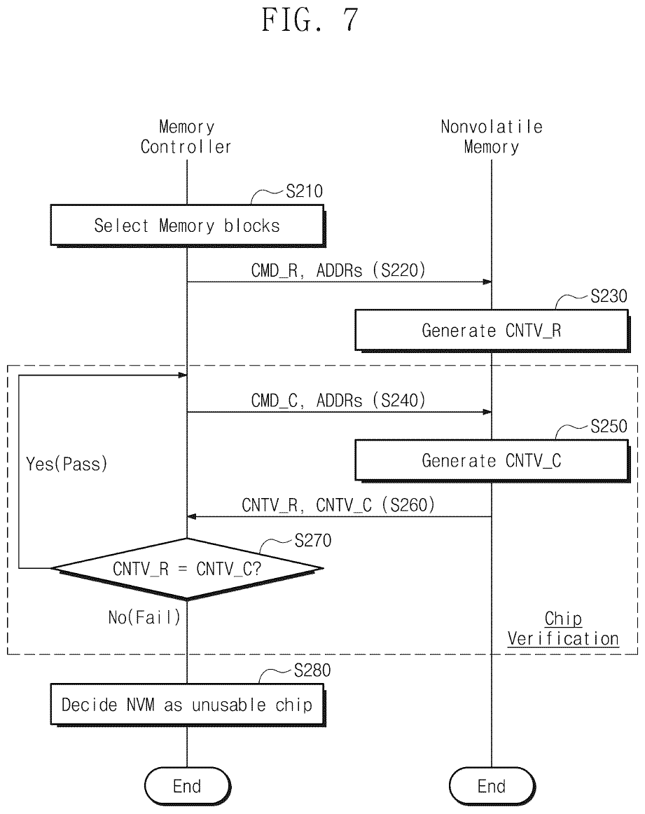

In operation S120, the storage device 100 performs the chip verification operation on the nonvolatile memory 120 at an arbitrary time point after the first power-on time point, based on the reference counting value CNTV_R. The chip verification operation will be described in detail with reference to FIGS. 7 to 11.

In some implementations, the arbitrary time point after the first power-on time point is associated with an end of life of the nonvolatile memory 120. For example, the arbitrary time point after the first power-on time point may be associated with a ratio of a program/erase cycle count (hereinafter referred to as a “threshold program/erase cycle count”) corresponding to an expected end of life of the nonvolatile memory 120.

For example, the storage device 100 may perform the chip verification operation on the nonvolatile memory 120 at a first time point after the first power-on time point, based on the reference counting value CNTV_R. The first time point may correspond to a first program/erase cycle count corresponding to a first ratio (e.g., 1%) of the threshold program/erase cycle count. For example, the first time point may correspond to a time point at which the program/erase operation of the nonvolatile memory 120 is performed as much as (or as many times as) a first program/erase cycle count, from or since the first power-on time point.

When a chip verification result in operation S120 indicates a fail, in operation S130, the storage device 100 may decide the nonvolatile memory 120 as an unusable chip. When the chip verification result in operation S120 indicates a pass, the storage device 100 may again perform operation S120. For example, the storage device 100 may perform the chip verification operation at a second time point after the first time point. In some implementations, the second time point corresponds to the first program/erase cycle count corresponding to the first ratio (e.g., 1%) of an threshold program/erase cycle count. For example, the second time point may correspond to a time point at which the program/erase operation of the nonvolatile memory 120 is performed as much as the first program/erase cycle count from or since the first time point.

In FIG. 6, and elsewhere in this disclosure, the description is given as the reference counting value CNTV_R corresponding to the number of stuck bits associated with memory blocks selected at the first power-on time point, but the present disclosure is not limited thereto. For example, the reference counting value CNTV_R may correspond to a number of stuck bits at various time points before the nonvolatile memory 120 is used by the user. The reference counting value CNTV_R may correspond to a number of stuck bits at a time point before a first time point at which a chip verification operation is performed; this time point can be referred to as a “reference time point,” which can include, but is not limited to, a first power-on time point or another time point before the nonvolatile memory 120 is used by the user. All description herein that refers to a “first power-on time point” can equally refer to a “reference time point.”

As described above, the storage device 100 may repeatedly perform the chip verification operation every one or more time points which are based on the threshold program/erase cycle count.

FIG. 7 illustrates a chip verification operating method of a storage device according to some implementations of the present disclosure. Referring to FIGS. 1, 3, and 7, in operation S210, the memory controller 110 selects one or more memory blocks among the plurality of memory blocks BLK1 to BLKz included in the nonvolatile memory 120.

In some implementations, the memory controller 110 selects two memory blocks among the plurality of memory blocks BLK1 to BLKz. For example, the memory controller 110 may select the first memory block BLK1 located at the uppermost of the plurality of memory blocks BLK1 to BLKz and the second memory block BLK2 adjacent to the first memory block BLK1.

In some implementations, the memory controller 110 selects the first memory block BLK1 located at the uppermost of the plurality of memory blocks BLK1 to BLKz vertically stacked on the substrate.

In operation S220, the memory controller 110 transfers a command (hereinafter referred to as a “reference value generating command CMD_R”) for generating the reference counting value CNTV_R and addresses ADDRs corresponding to the selected memory blocks to the nonvolatile memory 120. For example, the memory controller 110 may transfer the reference value generating command CMD_R and the addresses ADDRs corresponding to the selected memory blocks to the nonvolatile memory 120 at a first power-on time point.

In response to the reference value generating command CMD_R, in operation S230, the nonvolatile memory 120 generates the reference counting value CNTV_R associated with the selected memory blocks. For example, the nonvolatile memory 120 may count the number of stuck bits associated with the selected memory blocks and may generate the reference counting value CNTV_R. The nonvolatile memory 120 may store the reference counting value CNTV_R in a defect-free memory block among the plurality of memory blocks BLK1 to BLKz.

In operation S240, the memory controller 110 transfers a command (hereinafter referred to as a “comparison value generating command CMD_C”) for generating a counting value (hereinafter referred to as a “comparison counting value CNTV_C”) corresponding to the number of stuck bits associated with the selected memory blocks through a counting operation and the addresses ADDRs corresponding to the selected memory blocks to the nonvolatile memory 120. For example, the memory controller 110 may transfer the comparison value generating command CMD_C and the addresses ADDRs corresponding to the selected memory blocks to the nonvolatile memory 120 at an arbitrary time point after the first power-on time point. In some implementations, the arbitrary time point after the first power-on time point corresponds to a first program/erase cycle count corresponding to a first ratio (e.g., 1%) of the threshold program/erase cycle count after the first power-on time point.

In response to the comparison value generating command CMD_C, in operation S250, the nonvolatile memory 120 generates the comparison counting value CNTV_C associated with the selected memory blocks. For example, the nonvolatile memory 120 may count the number of stuck bits associated with the selected memory blocks and may generate the comparison counting value CNTV_C. The nonvolatile memory 120 may store the comparison counting value CNTV_C in the memory block where the reference counting value CNTV_R is stored. In some implementations, the nonvolatile memory 120 stores the comparison counting value CNTV_C in a memory block, which is different from the memory block where the reference counting value CNTV_R is stored, from among defect-free memory blocks.

In operation S260, the nonvolatile memory 120 transfers the reference counting value CNTV_R and the comparison counting value CNTV_C to the memory controller 110. For example, the nonvolatile memory 120 may transfer the reference counting value CNTV_R and the comparison counting value CNTV_C present in the defect-free memory block to the memory controller 110.

In operation S270, the memory controller 110 compares the received reference counting value CNTV_R and the received comparison counting value CNTV_C. For example, the memory controller 110 may compare the reference counting value CNTV_R and the comparison counting value CNTV_C and may determine whether the reference counting value CNTV_R is the same as the comparison counting value CNTV_C, based on a comparison result. In some implementations, instead of or in addition to determining whether the reference counting value CNTV_R is the same as the comparison counting value CNTV_C, the memory controller 110 can determine whether the values CNTV_R and CNTV_C jointly satisfy a condition, e.g., whether the values are within a threshold range from one another. For example, in some implementations, if CNTV_R and CNTV_C are different but similar (e.g., different by less than a threshold value), the memory controller 110 can determine that a micro crack has not expanded. The condition can be based on a difference between CNTV_R and CNTV_C.

That the reference counting value CNTV_R is different from the comparison counting value CNTV_C, or different from the comparison counting value CNTV_C by at least a threshold value, may mean that a range (e.g., dimension) of a micro crack present in the nonvolatile memory 120 is expanded. For example, when the reference counting value CNTV_R is different from the comparison counting value CNTV_C (or if the values CNTV_R, CNTV_C satisfy another condition), it may be determined that the result of the chip verification operation on the nonvolatile memory 120 indicates a fail. In this case, the memory controller 110 may perform operation S280.

That the reference counting value CNTV_R is the same as the comparison counting value CNTV_C may mean that a range (e.g., dimension) of a micro crack present in the nonvolatile memory 120 is uniform (or is not expanded). For example, when the reference counting value CNTV_R is the same as the comparison counting value CNTV_C, the memory controller 110 may again perform operation S240 at another time point after the first power-on time point.

In operation S280, the memory controller 110 may determine the nonvolatile memory 120 to be an unusable chip. For example, the memory controller 110 may control the nonvolatile memory 120 such that the use of the nonvolatile memory 120 is stopped. In some implementations, the memory controller 110 transfers information about the nonvolatile memory 120 (e.g., information indicating that the nonvolatile memory 120 has been determined as, or to be, an unusable chip) to the external device.

In FIG. 7, the nonvolatile memory 120 is illustrated as generating the reference counting value CNTV_R in response to the reference value generating command CMD_R and generating the comparison counting value CNTV_C in response to the comparison value generating command CMD_C, but the present disclosure is not limited thereto. For example, the nonvolatile memory 120 may generate the reference counting value CNTV_R at the first power-on time point (or other reference time point) internally or depending on an internal policy and may generate the comparison counting value CNTV_C at an arbitrary time point after the first power-on time point.

As described with reference to FIG. 7, the storage device 100 may repeatedly perform the chip verification operation on the nonvolatile memory 120 by generating one or more comparison counting values CNTV_Cs by repeatedly counting the number of stuck bits associated with selected memory blocks at one or more time points after the first power-on time point and comparing the reference counting value CNTV_R with each of the one or more comparison counting values CNTV_Cs.

FIG. 8 illustrates an operating method of a nonvolatile memory generating a counting value, according to some implementations of the present disclosure. Operations illustrated in FIG. 8 may correspond to operation S230 or S250 of FIG. 7.

Referring to FIGS. 1, 7, and 8, in operation S310, the nonvolatile memory 120 performs the erase operation on selected memory blocks. For example, the nonvolatile memory 120 may perform a first erase operation on the selected memory blocks when the nonvolatile memory 120 is powered on for the first time. For example, the nonvolatile memory 120 may perform a second erase operation on the selected memory blocks at an arbitrary time point after the first power-on time point.

In some implementations, the nonvolatile memory 120 performs the erase operation on a plane where the selected memory blocks are included. For example, the selected memory blocks may include the first memory block BLK1 located at the uppermost of the plurality of memory blocks BLK1 to BLKz vertically stacked on the substrate and the second memory block BLK2 adjacent to the first memory block BLK1. When the first memory block BLK1 and the second memory block BLK2 are included in a first plane, the nonvolatile memory 120 may perform the erase operation on the first plane. However, the present disclosure is not limited thereto. For example, the erase operation on the selected memory blocks may be performed in various units.

After the erase operation is normally performed, in operation S320, the nonvolatile memory 120 applies the stuck bit detection voltage V_SBD to word lines connected to the selected memory blocks. For example, after the first erase operation or the second erase operation is normally performed, the nonvolatile memory 120 may apply the stuck bit detection voltage V_SBD to the word lines connected to the selected memory blocks.

In operation S330, the nonvolatile memory 120 generates a counting value by counting the number of stuck bits detected when the stuck bit detection voltage V_SBD is applied to the word lines. For example, the nonvolatile memory 120 may generate the reference counting value CNTV_R by counting the number of stuck bits which are detected when the stuck bit detection voltage V_SBD is applied to the word lines after the first erase operation. For example, the nonvolatile memory 120 may generate the comparison counting value CNTV_C by counting the number of stuck bits which are detected when the stuck bit detection voltage V_SBD is applied to the word lines after the second erase operation.

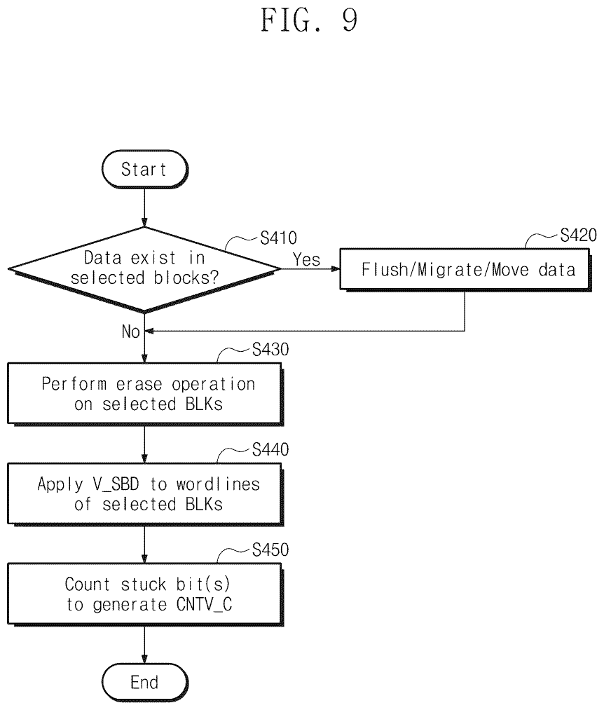

FIG. 9 illustrates an operating method of a nonvolatile memory generating a comparison counting value, according to some implementations of the present disclosure. Operations illustrated in FIG. 9 may correspond to operation S250 of FIG. 7.

Referring to FIGS. 1, 7, and 9, in operation S410, the nonvolatile memory 120 determines whether there exists data stored in selected memory blocks. When there exists data stored in selected memory blocks, the nonvolatile memory 120 performs operation S420. When there exist no data stored in selected memory blocks, the nonvolatile memory 120 performs operation S430.

In operation S420, the nonvolatile memory 120 flushes, migrates, or moves the stored data to one or more memory blocks different from the selected memory blocks.

In operation S430, the nonvolatile memory 120 performs the erase operation on the selected memory blocks. For example, the nonvolatile memory 120 may perform the second erase operation on the selected memory blocks at an arbitrary time point after the first power-on time point (or other reference time point).

After the erase operation is normally performed, in operation S440, the nonvolatile memory 120 applies the stuck bit detection voltage V_SBD to the word lines connected to the selected memory blocks. For example, after the second erase operation is normally performed, the nonvolatile memory 120 may apply the stuck bit detection voltage V_SBD to the word lines connected to the selected memory blocks.

In operation S450, the nonvolatile memory 120 generates a counting value by counting the number of stuck bits detected when the stuck bit detection voltage V_SBD is applied to the word lines. For example, the nonvolatile memory 120 may generate the comparison counting value CNTV_C by counting the number of stuck bits which are detected when the stuck bit detection voltage V_SBD is applied to the word lines after the second erase operation.

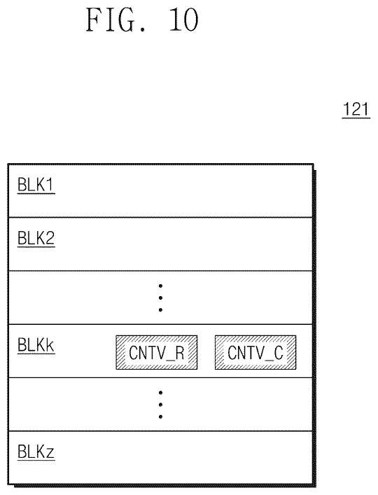

FIG. 10 illustrates a nonvolatile memory according to some implementations of the present disclosure. Referring to FIGS. 1, 7, and 10, the nonvolatile memory 120 may store the generated reference counting value CNTV_R and the generated comparison counting value CNTV_C in the k-th memory block BLKk, which is a defect-free memory block from among the plurality of memory blocks BLK1 to BLKz. For example, the nonvolatile memory 120 may generate the reference counting value CNTV_R and may store the generated reference counting value CNTV_R in the k-th memory block BLKk. Afterwards, the nonvolatile memory 120 may generate the comparison counting value CNTV_C and may store the comparison counting value CNTV_C in the k-th memory block BLKk.

In some implementations, the nonvolatile memory 120 stores the reference counting value CNTV_R and one or more comparison counting values CNTV_Cs. For example, when the storage device 100 repeatedly performs the chip verification operation, the nonvolatile memory 120 may store, in the k-th memory block BLKk, the reference counting value CNTV_R and the one or more comparison counting values CNTV_Cs generated by performing the chip verification operation.

In some implementations, when the nonvolatile memory 120 generates the one or more comparison counting values CNTV_Cs, the nonvolatile memory 120 may store the reference counting value CNTV_R and one comparison counting value CNTV_C. For example, when the storage device 100 repeatedly performs the chip verification operation, the nonvolatile memory 120 may store, in the k-th memory block BLKk, the reference counting value CNTV_R and the last generated comparison counting value CNTV_C.

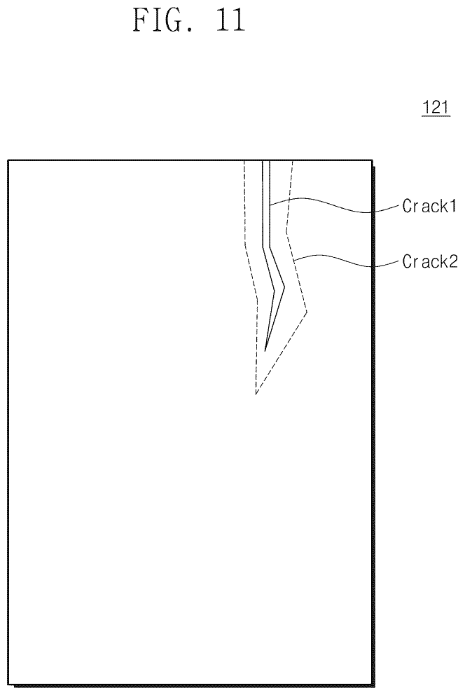

FIG. 11 illustrates a micro crack occurring in a nonvolatile memory. Referring to FIGS. 1 and 11, a first crack crack1 and a second crack crack2 may indicate cracks occurring in the memory cell array 121 of the nonvolatile memory 120 at different time points. For example, the first crack crack1 may indicate a crack occurring in the process of manufacturing the nonvolatile memory 120, and the second crack crack2 may indicate a crack which is formed as a range (e.g., dimension such as length, width, extent, etc.) of the first crack crack1 is expanded while the nonvolatile memory 120 is being used. For example, the first crack crack1 may be expanded to the second crack crack2 as the nonvolatile memory 120 is repetitively used.

In some implementations, the nonvolatile memory 120 may generate the reference counting value CNTV_R by counting the number of stuck bits due to the first crack crack1 at the first power-on time point (or other reference time point). The nonvolatile memory 120 may generate the comparison counting value CNTV_C by counting the number of stuck bits due to the second crack crack2 at an arbitrary time point after the first power-on time point. The nonvolatile memory 120 may transfer the reference counting value CNTV_R associated with the first crack crack1 and the comparison counting value CNTV_C associated with the second crack crack2 to the memory controller 110. The memory controller 110 may compare the reference counting value CNTV_R and the comparison counting value CNTV_C to perform the chip verification operation on the nonvolatile memory 120.

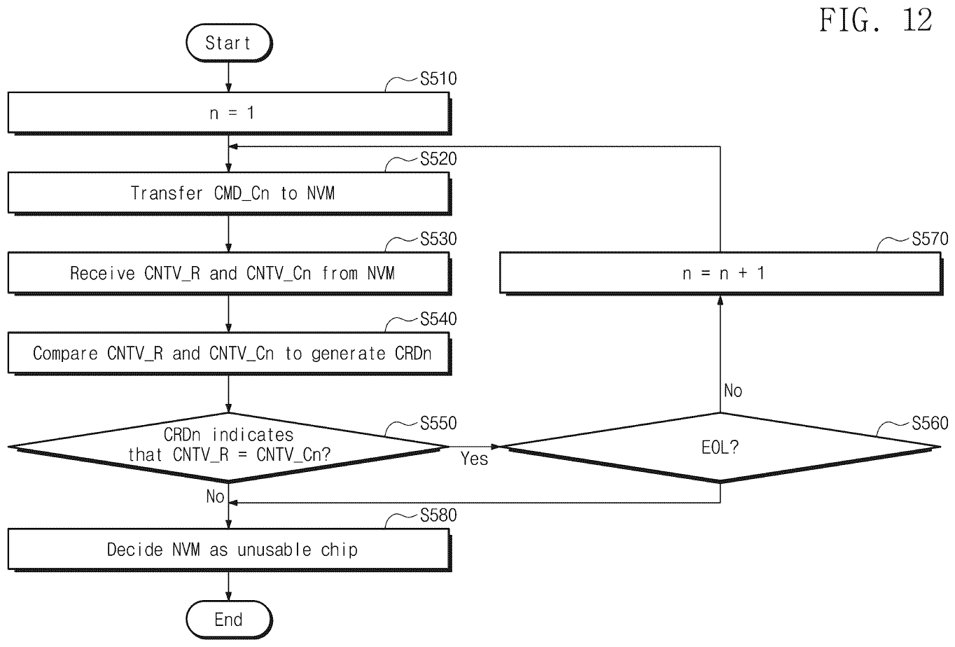

FIG. 12 illustrates an operating method of a memory controller according to some implementations of the present disclosure. Referring to FIGS. 1 and 12, in operation S510, a variable “n” is set to “1”. The variable “n” is used to describe the iteration of the chip verification operation of the memory controller 110, and the present disclosure is not limited thereto.

In operation S520, the memory controller 110 transfers an n-th comparison value generating command CMD_Cn to the nonvolatile memory 120 at an arbitrary time point after the first power-on time point (or other reference time point). For example, the memory controller 110 may transfer the n-th comparison value generating command CMD_Cn to the nonvolatile memory 120 at a first time point after the first power-on time point. In some implementations, the first time point corresponds to a time point at which the program/erase operation of the nonvolatile memory 120 is performed as much as a first program/erase cycle count from the first power-on time point.

In operation S530, the memory controller 110 receives the reference counting value CNTV_R and an n-th comparison counting value CNTV_Cn from the nonvolatile memory 120 as a response to the n-th comparison value generating command CMD_Cn.

In operation S540, the memory controller 110 compares the received reference counting value CNTV_R and the received n-th comparison counting value CNTV_Cn and may generate n-th comparison result data CRDn. For example, the memory controller 110 may generate the n-th comparison result data CRDn by comparing the reference counting value CNTV_R and the n-th comparison counting value CNTV_Cn based on an XOR logic operation.

In operation S550, the memory controller 110 determines whether the n-th comparison result data CRDn indicates that the reference counting value CNTV_R is the same as the n-th comparison counting value CNTV_Cn. When the n-th comparison result data CRDn indicate that the reference counting value CNTV_R is the same as the n-th comparison counting value CNTV_Cn, the memory controller 110 performs operation S560. When the n-th comparison result data CRDn indicate that the reference counting value CNTV_R is different from the n-th comparison counting value CNTV_Cn (or that the values CNTV_R, CNTV_Cn satisfy another condition), the memory controller 110 performs operation S580.

In some implementations, a value of the n-th comparison result data CRDn based on the XOR logical operation may be “0”. In this case, the n-th comparison result data CRDn may indicate that the reference counting value CNTV_R is the same as the n-th comparison counting value CNTV_Cn.

In some implementations, a value of the n-th comparison result data CRDn based on the XOR logical operation may be “1”. In this case, the n-th comparison result data CRDn may indicate that the reference counting value CNTV_R is different from the n-th comparison counting value CNTV_Cn.

When the n-th comparison result data CRDn indicate that the reference counting value CNTV_R is the same as the n-th comparison counting value CNTV_Cn, in operation S560, the memory controller 110 may determine whether the nonvolatile memory 120 is in an EOL (end of life) state. For example, the memory controller 110 may determine whether the nonvolatile memory 120 reaches an expected end of life.

When the nonvolatile memory 120 is in the EOL state, the memory controller 110 performs operation S580. When the nonvolatile memory 120 is not in the EOL state, the memory controller 110 performs operation S570.

When the nonvolatile memory 120 is not in the EOL state, the memory controller 110 may increase the variable “n” by “1”. Afterwards, the memory controller 110 may perform operation S520 at a second time point after the first time point. In some implementations, the second time point corresponds to a time point at which the program/erase operation of the nonvolatile memory 120 is performed as much as the first program/erase cycle count from the first time point.

When the n-th comparison result data CRDn indicate that the reference counting value CNTV_R is different from the n-th comparison counting value CNTV_Cn or when the nonvolatile memory 120 is in the EOL state, in operation S580, the memory controller 110 may determine the nonvolatile memory 120 to be an unusable chip. The memory controller 110 may manage the nonvolatile memory 120 based on determining the nonvolatile memory 120 to be an unusable chip. For example, the memory controller 110 may control the nonvolatile memory 120 such that the use of the nonvolatile memory 120 is stopped or otherwise reduced.

As described with reference to FIG. 12, the storage device 100 may generate one or more comparison counting values CNTV_Cs by repeatedly counting the number of stuck bits associated with selected memory blocks at one or more time points after the first power-on time point, may generate one or more comparison result data CRDs by comparing the reference counting value CNTV_R with the one or more comparison counting values CNTV_Cs, and may repeatedly perform the chip verification operation on the nonvolatile memory 120 based on each of the one or more comparison result data CRDs. The storage device 100 may repeatedly perform the chip verification operation until the nonvolatile memory 120 is determined as being in the EOL state or as an unusable chip.

FIG. 13 illustrates a storage device according to some implementations of the present disclosure. Referring to FIG. 9, a storage device 200 may include a memory controller 210 and a nonvolatile memory 220. The storage device 200 may perform the chip verification operations described with reference to FIGS. 1 to 9.

In the example of FIG. 13, a built-in self-test (BIST) circuit 221 which is implemented in the form of an on-chip module may compare the reference counting value CNTV_R with the comparison counting values CNTV_Cs, respectively. For example, the BIST circuit 221 may generate one or more comparison result data CRDs by comparing the reference counting value CNTV_R with each of one or more comparison counting values CNTV_Cs and may transmit the one or more comparison result data CRDs to the memory controller 210. The chip verification circuit 211 of the memory controller 210 may repeatedly perform the chip verification operation on the nonvolatile memory 220 based on the one or more comparison result data CRDs.

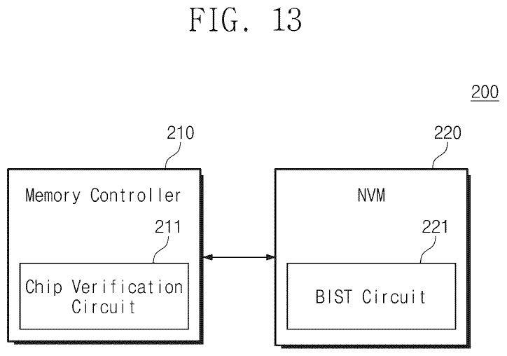

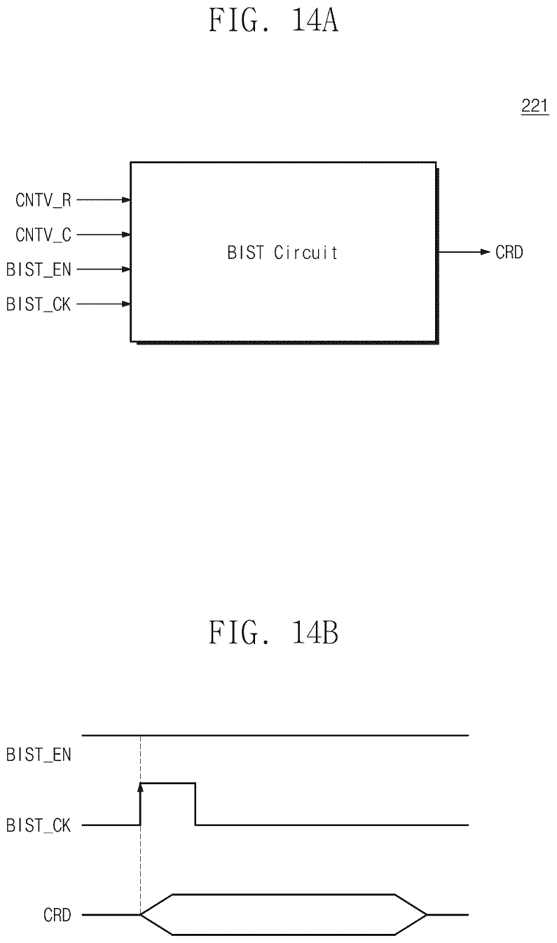

FIGS. 14A and 14B illustrate a BIST circuit of FIG. 13. Referring to FIGS. 3, 13, and 14, the BIST circuit 221 may receive the reference counting value CNTV_R and the comparison counting value CNTV_C from the page buffer 123. For example, the BIST circuit 221 may receive the reference counting value CNTV_R and the comparison counting value CNTV_C at a first time point after the first power-on time point.

The BIST circuit 221 may compare the received reference counting value CNTV_R and the received comparison counting value CNTV_C and may generate the comparison result data CRD.

The BIST circuit 221 may receive a BIST enable signal BIST_EN from the control logic circuit 126. The BIST circuit 221 may be activated based on the BIST enable signal BIST_EN. For example, when the BIST enable signal BIST_EN is at a high level, the BIST circuit 221 may be activated.

In some implementations, the BIST enable signal BIST_EN maintains a low level before the first power-on time point (or other reference time point) and may maintain the high level after the first power-on time point. For example, the BIST enable signal BIST_EN may maintain the low level before the nonvolatile memory 220 generates the reference counting value CNTV_R and may maintain the high level after the nonvolatile memory 220 generates the reference counting value CNTV_R.

The BIST circuit 221 may receive a BIST clock signal BIST_CK from the control logic circuit 126. The BIST circuit 221 may transmit the comparison result data CRD to the memory controller 210 based on the BIST clock signal BIST_CK.

Referring to FIGS. 14A and 14B, the BIST circuit 221 may output the comparison result data CRD to the memory controller 210 in response to the rising edge of the BIST clock signal BIST_CK.

In some cases, the reference counting value CNTV_R and the comparison counting value CNTV_C may be different from each other (or satisfy another condition). In this case, in response to the rising edge of the BIST clock signal BIST_CK, the BIST circuit 221 may output the comparison result data CRD indicating that the reference counting value CNTV_R and the comparison counting value CNTV_C are different. For example, when the BIST circuit 221 generates the comparison result data CRD based on the XOR logical operation, the BIST circuit 221 may output the comparison result data CRD having a value of “0x01”.

In some cases, the reference counting value CNTV_R may be the same as the comparison counting value CNTV_C. In this case, in response to the rising edge of the BIST clock signal BIST_CK, the BIST circuit 221 may output the comparison result data CRD indicating that the reference counting value CNTV_R is the same as the comparison counting value CNTV_C. For example, when the BIST circuit 221 generates the comparison result data CRD based on the XOR logical operation, the BIST circuit 221 may output the comparison result data CRD having a value of “0x00”.

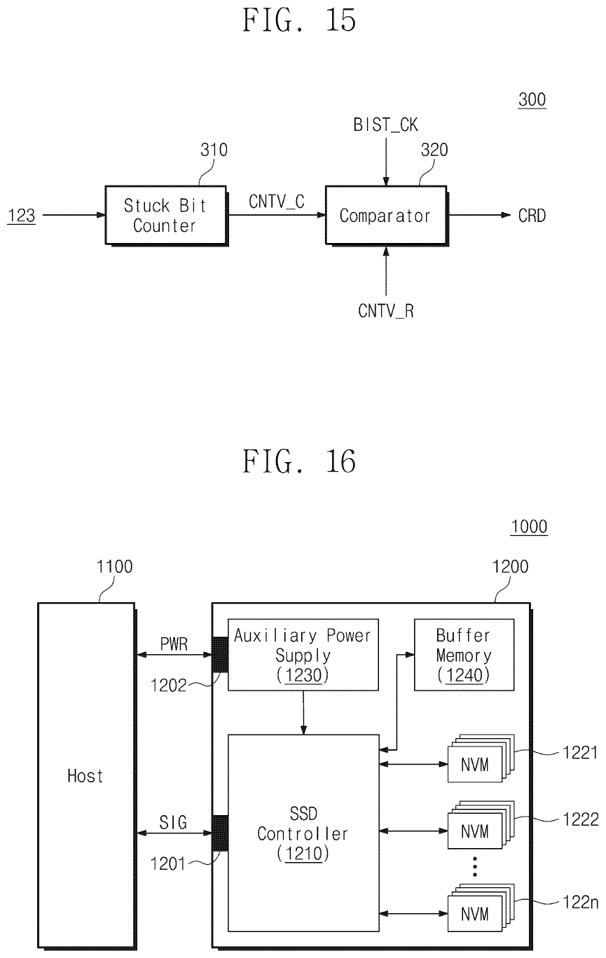

FIG. 15 illustrates an operating method of a comparison logic circuit according to some implementations of the present disclosure. Referring to FIGS. 3, 13, and 15, the BIST circuit 221 may include a stuck bit counter 310 and a comparator 320.

The stuck bit counter 310 may generate the comparison counting values CNTV_Cs by counting stuck bits at an arbitrary time point after the first power-on time point (or other reference time point).

The comparator 320 may receive the comparison counting value CNTV_C from the stuck bit counter 310 and may receive the reference counting value CNTV_R from the memory cell array 121. The comparator 320 may compare the reference counting value CNTV_R and the comparison counting value CNTV_C and may generate the comparison result data CRD. The comparator 320 may transmit the comparison result data CRD to the chip verification circuit 211, based on the BIST clock signal BIST_CK received from the control logic circuit 126. As discussed above, the comparison result data CRD may indicate whether the reference counting value CNTV_R and the comparison counting value CNTV_C satisfy a condition, e.g., whether the values are identical or whether the values are within a threshold range from one another.

FIG. 16 illustrates an SSD system to which a nonvolatile memory according to the present disclosure is applied. Referring to FIG. 16, an SSD system 1000 may include a host 1100 and a storage device 1200. The storage device 1200 may exchange a signal SIG with the host 1100 through a signal connector 1201 and may receive a power PWR through a power connector 1202. The storage device 1200 may include a solid state drive (SSD) controller 1210, a plurality of packages 1221 to 122n each including a plurality of nonvolatile memories NVMs, an auxiliary power supply 1230, and a buffer memory 1240.

The SSD controller 1210 may control the plurality of nonvolatile memories NVMs in response to the signal SIG received from the host 1100. The plurality of nonvolatile memories NVMs may operate under control of the SSD controller 1210. The auxiliary power supply 1230 is connected to the host 1100 through the power connector 1202. The auxiliary power supply 1230 may be charged by the power PWR received from the host 1100. When a power supply from the host 1100 is not smooth, the auxiliary power supply 1230 may provide a power of the storage device 1200. The buffer memory 1240 may be used as a buffer memory of the storage device 1200.

The storage device 200 may perform the chip verification operation described with reference to FIGS. 1 to 15. In some implementations, the SSD controller 1210 includes a chip verification circuit configured to perform the chip verification operation for each of the plurality of nonvolatile memories NVMs. The SSD controller 1210 may generate the comparison result data CRD by comparing the reference counting value CNTV_R and the comparison counting value CNTV_C, for each of the plurality of nonvolatile memories NVMs. The SSD controller 1210 may perform the chip verification operation on the nonvolatile memories NVMs, based on the comparison result data CRDs respectively associated with the nonvolatile memories NVMs.

In some implementations, each of the nonvolatile memories NVMs includes a BIST circuit for comparing the reference counting value CNTV_R and the comparison counting value CNTV_C. Each of the nonvolatile memories NVMs may generate the comparison result data CRD by comparing the reference counting value CNTV_R and the comparison counting value CNTV_C through the BIST circuit. Each of the nonvolatile memories NVMs may transfer the comparison result data CRD to the SSD controller 1210. The SSD controller 1210 may perform the chip verification operation on the nonvolatile memories NVMs, based on the comparison result data CRDs respectively associated with the nonvolatile memories NVMs.

In some implementations, the SSD controller 1210 may perform the chip verification operation based on different program/erase cycle counts of the nonvolatile memories NVMs.

For example, the nonvolatile memories NVMs included in the first package 1221 may be vertically stacked on the substrate. In this case, the SSD controller 1210 may perform the chip verification operation on the nonvolatile memory NMV located at the uppermost position in the stack and the nonvolatile memory NVM located at the lowermost position in the stack, based on a first program/erase cycle count. The SSD controller 1210 may perform the chip verification operation on the remaining nonvolatile memories NVMs, based on a second program/erase cycle count greater than the first program/erase cycle count. However, the present disclosure is not limited thereto. For example, depending on a stacked shape of the nonvolatile memories NVMs in a package, the SSD controller 1210 may perform the chip verification operation on each nonvolatile memory NVM, based on different program/erase cycle counts of the nonvolatile memories NVMs.

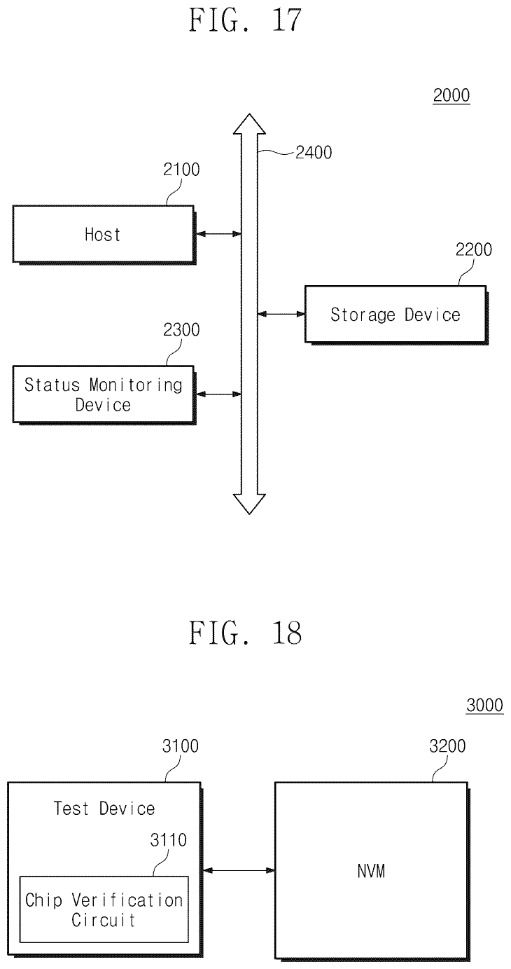

FIG. 17 illustrates a storage system according to some implementations of the present disclosure. Referring to FIG. 17, a storage system 2000 may include a host 2100, a storage device 2200, a status monitoring device 2300, and a bus 2400. In FIG. 17, the storage device 2200 may correspond to the storage device 100 of FIG. 1, the storage device 200 of FIG. 13, and the storage device 1200 of FIG. 16. The host 2100, the storage device 2200, and the status monitoring device 2300 may communicate with each other through the bus 2400. In some implementations, the storage system 2000 refers to a computing system, which is configured to process a variety of information, such as a personal computer (PC), a notebook, a laptop, a server, a workstation, a tablet PC, a smartphone, a digital camera, or a black box.

The host 2100 may control all the operations of the storage system 2000. For example, the host 2100 may store data in the storage device 2200 or may read data stored in the storage device 2200. The storage device 2200 may store data under control of the host 2100 or may provide data stored therein to the host 2100.

The storage device 2200 may perform the chip verification operation described with reference to FIGS. 1 to 15. The storage device 2200 may transmit a result of the chip verification operation to the host 2100 or the status monitoring device 2300.

The status monitoring device 2300 may perform a health check operation on the storage device 2200. The status monitoring device 2300 may obtain telemetry data TD associated with the health status of the storage device 2200 by performing the health check operation. The status monitoring device 2300 may store the obtained telemetry data TD. In some implementations, the telemetry data TD includes at least one of P/E cycle information, program count information, erase count information, read count information, error bit count information, and threshold voltage distribution information. However, the present disclosure is not limited thereto. For example, the telemetry data TD may include a variety of information associated with the health status of the storage device 2200. In some implementations, the status monitoring device 2300 is implemented with a software device or a firmware module. The status monitoring device 2300 may be referred to as a “telemetry”.

In some implementations, the status monitoring device 2300 provides the telemetry data TD to the host 2100. The host 2100 may control the storage device 2200 based on the received telemetry data TD. For example, based on the telemetry data TD received from the status monitoring device 2300, the host 2100 may identify the nonvolatile memory NVM, which performs an abnormal operation, from among the plurality of nonvolatile memories NVMs included in the storage device 2200. In this case, the host 2100 may control the storage device 2200 such that the use of the identified nonvolatile memory NVM is stopped.

In some implementations, the status monitoring device 2300 provides the telemetry data TD to the storage device 2200. The storage device 2200 may manage the plurality of nonvolatile memories NVMs included in the storage device 2200, based on the received telemetry data TD. For example, based on the telemetry data TD received from the status monitoring device 2300, the storage device 2200 may identify the nonvolatile memory NVM, which performs an abnormal operation, from among the plurality of nonvolatile memories NVMs. In this case, the storage device 2200 may determine that the identified nonvolatile memory NVM is an unusable chip, such that the use of the identified nonvolatile memory NVM is stopped or otherwise altered (e.g., reduced).

In some implementations, the status monitoring device 2300 performs the health check operation on the storage device 2200 and obtains a result of the chip verification operation performed by the storage device 2200. For example, the status monitoring device 2300 may perform the health check operation on the storage device 2200 and may obtain information about unusable chips among the plurality of nonvolatile memories NVMs included in the storage device 2200. The status monitoring device 2300 may store the obtained information about unusable chips as the telemetry data TD. In this case, the status monitoring device 2300 may provide the telemetry data TD to the host 2100. The host 2100 may control the storage device 2200 based on the telemetry data TD from the status monitoring device 2300 such that the use of an unusable chip included in the storage device 2200 is stopped.

In some implementations, the status monitoring device 2300 receives, from storage device 2200, the result of the chip verification operation performed by the storage device 2200. For example, the status monitoring device 2300 may receive the information about unusable chips among the plurality of nonvolatile memories NVMs included in the storage device 2200. The status monitoring device 2300 may store the received information about unusable chips as the telemetry data TD. In this case, the status monitoring device 2300 may provide the telemetry data TD to the host 2100. The host 2100 may control the storage device 2200 based on the telemetry data TD from the status monitoring device 2300 such that the use of an unusable chip included in the storage device 2200 is stopped.

In FIG. 17, the status monitoring device 2300 is illustrated as external to the storage device 2200, but the present disclosure is not limited thereto. For example, the status monitoring device 2300 may be implemented within the host 2100 in the form of a software device or a firmware module. As another example, the status monitoring device 2300 may be implemented within the storage device 2200 in the form of a software device or a firmware module.

FIG. 18 illustrates a test system according to some implementations of the present disclosure. Referring to FIG. 18, a test system 3000 may include a test device 3100 and a nonvolatile memory 3200. The test device 3100 may perform various test operations on the nonvolatile memory 3200. The test device 3100 may include a chip verification circuit 3110. The chip verification circuit 3110 may be configured to perform the chip verification operations described with reference to FIGS. 1 to 15. For example, the test device 3100 may be configured to determine whether a range of a micro crack present in the nonvolatile memory 3200 increases, by performing the chip verification operation on the nonvolatile memory 3200.

In the above description, components according to the present disclosure are described by using the terms “first”, “second”, “third”, etc. However, the terms “first”, “second”, “third”, etc. may be used to distinguish components from each other and do not limit the present disclosure. For example, the terms “first”, “second”, “third”, etc. do not involve an order or a numerical meaning of any form.

According to the present disclosure, a storage device may detect whether a micro crack is expanded, in various use environments, by periodically monitoring the micro crack present in a nonvolatile memory. Accordingly, a storage device including a nonvolatile memory with improved reliability and a memory controller and an operating method of the storage device are provided.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While the present disclosure includes description of various examples, it will be apparent to those of ordinary skill in the art that various changes and modifications may be made thereto without departing from the spirit and scope of the present disclosure.

What is claimed is:

1. A storage device comprising:
a first nonvolatile memory including a plurality of memory blocks including a first memory block, wherein the first nonvolatile memory is configured to:
generate a reference counting value by counting a number of stuck bits associated with the first memory block at a reference time point, and
generate a comparison counting value by counting a number of stuck bits associated with the first memory block at a first time point after the reference time point; and
a memory controller configured to:
receive the reference counting value and the comparison counting value from the first nonvolatile memory,
generate comparison result data by comparing the reference counting value with the comparison counting value, and
perform a chip verification operation on the first nonvolatile memory based on the comparison result data.

2. The storage device of claim 1, wherein the first time point is associated with a first program/erase cycle count of the first memory block.

3. The storage device of claim 1, wherein the first nonvolatile memory is configured to count the number of stuck bits associated with the first memory block at the reference time point by applying a stuck bit detection voltage to word lines connected to the first memory block, and
wherein a bit line connected to a memory cell having a threshold voltage higher than the stuck bit detection voltage, from among memory cells of the first memory block, is associated with the stuck bits.

4. The storage device of claim 1, wherein the first nonvolatile memory is configured to:
generate the reference counting value by performing a first erase operation on the first memory block; and
generate the comparison counting value after performing a second erase operation on the first memory block.

5. The storage device of claim 4, wherein the first nonvolatile memory is configured to, before the second erase operation is performed:
determine whether data is stored in the first memory block, and
based on determining that data is stored in the first memory block, migrate the stored data to another memory block of the plurality of memory blocks.

6. The storage device of claim 1, wherein the first nonvolatile memory is configured to generate the comparison result data based on an XOR logical operation.

7. The storage device of claim 6, wherein the memory controller is configured to determine that the first nonvolatile memory is defective based on a value of the comparison result data being “1”.

8. The storage device of claim 6, wherein the memory controller is configured to repeat the chip verification operation on the first nonvolatile memory based on a value of the comparison result data being “0”.

9. The storage device of claim 1, wherein the plurality of memory blocks are connected to a plurality of bit lines extending in a first direction and are vertically stacked along the first direction, and
wherein the first memory block is an uppermost one of the plurality of memory blocks.

10. The storage device of claim 1, further comprising a second nonvolatile memory and a third nonvolatile memory,
wherein the first to third nonvolatile memories are vertically stacked on a substrate,
wherein the second nonvolatile memory is located between the first nonvolatile memory and the third nonvolatile memory, and
wherein the memory controller is configured to:
perform the chip verification operation based on a first program/erase cycle count of the first nonvolatile memory and the third nonvolatile memory; and
perform the chip verification operation based on a second program/erase cycle count of the second nonvolatile memory, wherein the first program/erase cycle count is smaller than the second program/erase cycle count.

11. The storage device of claim 1, wherein the reference time point is a time when the first nonvolatile memory is powered on for the first time.

12. The storage device of claim 1, wherein the memory controller is configured to generate the reference counting value and the comparison counting value by further counting numbers of stuck bits associated with a second memory block of the plurality of memory blocks,
wherein the second memory block is adjacent to the first memory block.

13. A storage device comprising:
a first nonvolatile memory including a plurality of memory blocks including a first memory block, wherein the first nonvolatile memory is configured to:
generate a reference counting value by counting a number of stuck bits associated with the first memory block at a reference time point,
generate a comparison counting value by counting a number of stuck bits associated with the first memory block at a first time point after the reference time point, and
generate comparison result data by comparing the reference counting value with the comparison counting value; and
a memory controller configured to:
receive the comparison result data from the first nonvolatile memory, and
perform a chip verification operation on the first nonvolatile memory based on the comparison result data.

14. The storage device of claim 13, wherein the first time point is associated with a first program/erase cycle count of the first memory block.

15. The storage device of claim 13, wherein the first nonvolatile memory is configured to apply a stuck bit detection voltage to word lines connected to the first memory block, and
wherein a bit line connected to a memory cell having a threshold voltage higher than the stuck bit detection voltage, from among memory cells of the first memory block, is associated with the stuck bits.

16. The storage device of claim 13, wherein the first nonvolatile memory is configured to:
generate the reference counting value by performing a first erase operation on the first memory block; and
generate the comparison counting value after performing a second erase operation on the first memory block.

17. The storage device of claim 13, wherein the first nonvolatile memory is configured to generate the comparison result data based on an XOR logical operation.

18. The storage device of claim 13, wherein the plurality of memory blocks are connected to a plurality of bit lines extending in a first direction and are vertically stacked along the first direction, and
wherein the first memory block is located an uppermost one of the plurality of memory blocks.

19. An operating method of a storage device which includes a nonvolatile memory including a first memory block, and a memory controller configured to control the nonvolatile memory, the method comprising:
generating, at the nonvolatile memory, a reference counting value by counting a number of stuck bits associated with the first memory block at a reference time point;
generating, at the nonvolatile memory, a first comparison counting value by counting a number of stuck bits associated with the first memory block at a first time point after the reference time point;
transmitting the reference counting value and the first comparison counting value from the nonvolatile memory to the memory controller;
generating, at the memory controller, first comparison result data by comparing the reference counting value and the first comparison counting value; and
performing, at the memory controller, a chip verification operation on the nonvolatile memory based on the first comparison result data.

20. The method of claim 19, wherein the first time point is associated with a first program/erase cycle count of the first memory block.
